(19) United States
(12) Patent Application Publication
(10) Pub. No.: US 2008/0216959 A1
(43) Pub. Date: Sep. 11, 2008

(54) PLASMA PROCESSING APPARATUS

(76) Inventors: HIROYUKI KOBAYASHI, Kodaira (JP); Kenji Maeda, Sagamihara (JP); Masaru Izawa, Hino (JP); Kenetsu Yokogawa, Tsurugashima (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/835,446

(22) Filed: Aug. 8, 2007

(30) Foreign Application Priority Data
Mar. 9, 2007 (JP) 2007-060369

(51) Int. Cl. H01L 21/306

(52) U.S. Cl. 156/345.55; 156/345.1

(57) ABSTRACT

The present invention provides a plasma processing apparatus which has the function of removing a deposit adhering to the periphery of the backside of a sample and has high throughput and low cost. That is, a deposit removal unit for removing the deposit on the periphery of the backside of the sample by pulsed laser irradiation is connected to an atmosphere-side transfer chamber of the plasma processing apparatus.

### CLAIM OF PRIORITY

The present invention application claims priority from Japanese application JP2007-060369 filed on Mar. 9, 2007, the content of which is hereby incorporated by reference into this application.

### FIELD OF THE INVENTION

The present invention relates to plasma processing apparatuses for use in manufacturing semiconductors, and more particularly, to a plasma processing apparatus which removes a film deposited on the periphery of the backside of a sample subjected to plasma processing.

### BACKGROUND OF THE INVENTION

In a manufacturing process of a semiconductor device such as DRAM or a microprocessor, plasma etching or plasma CVD utilizing a weakly ionized plasma is widely used. To improve the yield in the manufacturing process of the semiconductor device, it is important to reduce the occurrence of particle contamination during the plasma processing. With the adoption of new semiconductor materials and the development of finer structure of semiconductor devices, processing gas with a large deposition property has been used more frequently. With this, a deposited film is formed on the periphery of the backside of a sample during the plasma processing, and the deposited film may peel off, for example, during the transfer of the sample and disadvantageously become a particle.

There have been proposed several methods for removing such a deposit formed on the periphery of the backside of the sample.

For example, Japanese Patent Application Laid-Open Publication No. 2006-319043 describes a method of removing the deposit by generating cleaning plasma along the periphery of the backside of the sample in a plasma processing chamber for etching.

U.S. Pat. No. 2005/0284568 A1, and Japanese Patent Application Laid-Open Publication Nos. 2006-287170, 2006-49870, 2006-49869, and 2006-287169 propose methods in which a dedicated apparatus independent of a plasma processing apparatus activates and removes the deposit adhering to the periphery of the backside of the sample by reactive gas. That is, U.S. Pat. No. 2005/0284568 A1 discloses a structure for removing an undesired film by supplying reactive gas from a nozzle and applying light to the front side and backside of a wafer. Japanese Patent Application Laid-Open Publication No. 2006-287170 discloses a structure for flowing an undesired substance along the periphery of a substrate by introducing reactive gas for removing the undesired substance into a guide passage where the periphery of the substrate is placed.

Japanese Patent Application Laid-Open Publication No. 2006-49870 discloses a structure for supplying reactive gas such as ozone from an outlet nozzle and applying a focused laser from an irradiator disposed above a substrate to the periphery of the substrate supported on a stage.

Further, Japanese Patent Application Laid-Open Publication Nos. 2006-49869 and 2006-287169 disclose a structure for locally heating by a heater the periphery of the backside of a wafer supported on a stage and blowing reactive gas for removing an undesired film from a reactive gas outlet nozzle near the locally heated region.

### SUMMARY OF THE INVENTION

In the case of the method disclosed in Japanese Patent Application Laid-Open Publication No. 2006-319043 for removing the deposit adhering to the periphery of the backside of the sample in the plasma processing chamber for etching and the like, since the plasma processing chamber is not specialized in removing the deposit, the removal speed is not necessarily fast. Further, the next sample cannot undergo etching and the like during the removal of the deposit, which reduces the throughput.

The apparatuses disclosed in U.S. Pat. No. 2005/0284568 A1, and Japanese Patent Application Laid-Open Publication Nos. 2006-287170, 2006-49870, 2006-49869, and 2006-287169 each cause a chemical reaction in the deposit by supplying reactive gas and heat, so that the deposit is activated and removed. With the installation of such a dedicated apparatus, etching a sample and removing the deposit adhering to a processed sample can be performed simultaneously, so that the throughput can be increased. However, these apparatuses need to supply reactive gas, and installing such a dedicated processing apparatus separate from the plasma processing apparatus increases the size and the cost of the entire system, compared to a system that performs deposit removal as well as plasma processing in the plasma processing chamber. Further, after the completion of predetermined processing in the plasma processing apparatus, the sample having the deposit on the periphery of the backside is stored in a front opening unified pod (FOUP) and then transported to the dedicated apparatus for removing the deposit. In this case, there is a risk that the detachment of the deposit contaminates the insides of the FOUP.

It is an object of the present invention to provide a plasma processing apparatus which can efficiently remove a deposit adhering to the periphery of the backside of a processed sample and has high throughput and low cost.

It is another object of the invention to provide a plasma processing apparatus which can efficiently remove a deposit adhering to the periphery of the backside of a processed sample and has low risk of contaminating a FOUP.

A representative example of the invention is a plasma processing apparatus having a plasma processing chamber for processing a sample in a reduced-pressure environment, including a deposit removal unit for evaporating and removing a deposit adhering to the sample by applying a pulsed laser beam to a periphery of a backside of the sample processed in the plasma processing chamber.

According to the invention, the function of removing the deposit adhering to the periphery of the backside of the sample by heating and evaporating the deposit is provided to the plasma processing apparatus, thereby advantageously reducing the apparatus cost, enhancing the throughput, and reducing the risk of contaminating the FOUP.

### BRIEF DESCRIPTION OF THE DRAWINGS

These and other features, objects and advantages of the present invention will become more apparent from the following description when taken in conjunction with the accompanying drawings wherein:

FIG. 1 is a top view showing the general configuration of a plasma processing apparatus according to a first embodiment of the present invention;

FIG. 2 is a longitudinal sectional view showing the outline of a deposit removal unit in FIG. 1;

FIG. 3 is a plan view showing the outline of a stage in FIG. 2;

FIG. 4 is an illustration of assistance in explaining the detail structure in the vicinity of the periphery of the backside of a sample in FIG. 2;

FIG. 5 is an illustration of assistance in explaining how to change a laser irradiation position;

FIG. 6A is an explanatory graph for comparing the characteristics between a continuous wave oscillation (CW) type laser and a pulsed laser;

FIG. 6B is an explanatory graph for comparing the characteristics between a continuous wave oscillation (CW) type laser and a pulsed laser;

FIG. 7 is a time chart showing a processing sequence according to the first embodiment;

FIG. 8 is an illustration showing the flow of transfer of the sample in the plasma processing apparatus, according to the first embodiment;

FIG. 9A is an illustration of assistance in explaining the mechanism of how a deposit adheres to the periphery of the backside of the sample;

FIG. 9B is an illustration of assistance in explaining the mechanism of how a deposit adheres to the periphery of the backside of the sample;

FIG. 10 is a longitudinal sectional view showing the outline of a deposit removal unit according to a second embodiment of the invention;

FIG. 11 is an illustration showing the general configuration of a plasma processing apparatus and showing the flow of transfer of the sample in the plasma processing apparatus, according to a third embodiment of the invention;

### DETAILED DESCRIPTION OF THE PREFERRED EMBODIMENTS

According to a representative embodiment of the invention, a plasma processing apparatus has a plasma processing chamber and an atmosphere-side transfer robot installed in an atmosphere-side transfer chamber, a deposit removal unit for removing a deposit on the periphery of the backside of a sample is connected to the atmosphere-side transfer chamber, and the atmosphere-side transfer robot transfers the sample between the atmosphere-side transfer chamber and the deposit removal unit. Therefore, it is possible to share an aligner and the atmosphere-side transfer robot. That is, compared to the case where the plasma processing apparatus and the unit for removing the deposit on the periphery of the backside of the sample are independent of each other, there are advantages that the apparatus cost is reduced, the throughput is enhanced, and the space necessary for apparatus installation is reduced.

Hereinafter, embodiments of the present invention will be described with reference to the accompanying drawings.

### First Embodiment

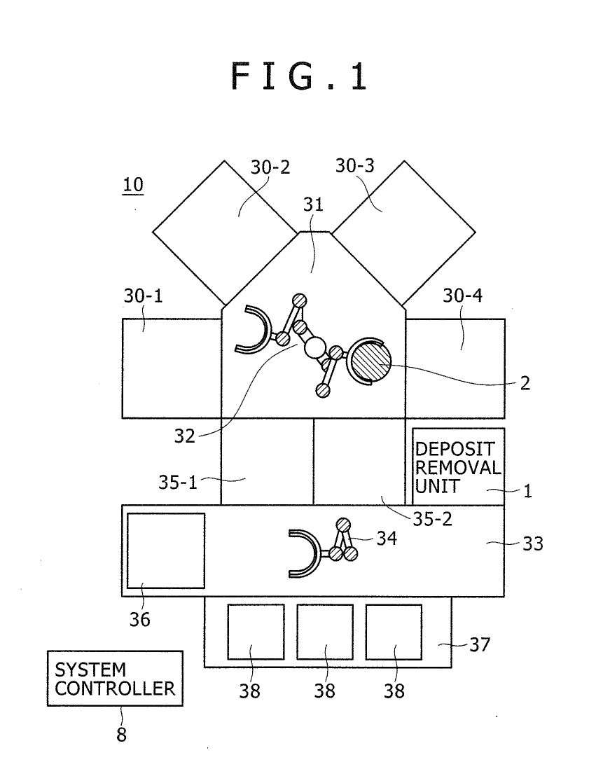

A first embodiment of the invention will be described with reference to related drawings. FIG. 1 is a top view showing the general configuration of a plasma processing apparatus according to the first embodiment of the invention. The plasma processing apparatus according to this embodiment is configured with a plasma processing unit 10, a deposit removal unit 1 for removing a deposit formed on the periphery of the backside of a sample processed by the plasma processing unit, and a system controller 8.

In the plasma processing unit 10 according to this embodiment, four plasma processing chambers 30 (30-1 to 30-4) and two lock chambers 35 (35-1 and 35-2) are connected to a vacuum-side transfer chamber 31. In the vacuum-side transfer chamber 31, there is installed a vacuum-side transfer robot 32 for transferring a sample 2 such as a wafer. The plasma processing unit 10 has a vacuum processing chamber; a specimen stage, installed in the vacuum processing chamber, for mounting the sample thereon; a supply source of an electromagnetic field for generating plasma; a supply source of processing gas; and the like (all of which are not shown). Further, a turbo-molecular pump (not shown) for reducing a pressure in the chamber is connected to the vacuum processing chamber.

An atmosphere-side transfer chamber 33 is connected to a vacuum-side transfer system (the vacuum-side transfer chamber 31 and the vacuum-side transfer robot 32) through the lock chambers 35 for use in atmosphere/vacuum switching. In the atmosphere-side transfer chamber 33, there are installed an atmosphere-side transfer robot 34 for transferring the sample and an aligner 36 for detecting the notch position and the center position of the sample 2 while rotating the sample. Further, at the atmosphere-side transfer chamber 33, there is installed a wafer station 37 in which front opening unified pods (FOUP) 38 for storing samples are installed.

Further, the deposit removal unit 1 for cleaning the periphery of the sample is connected to the atmosphere-side transfer chamber 33. If the deposit removal unit 1 is formed like a square in a plan view and installed in a space (shaped like a substantially square) surrounded by the lock chamber 35, the plasma processing chamber 30, and the atmosphere-side transfer chamber 33 as shown in FIG. 1, there is an advantage that the installation space of the entire plasma processing apparatus does not increase.

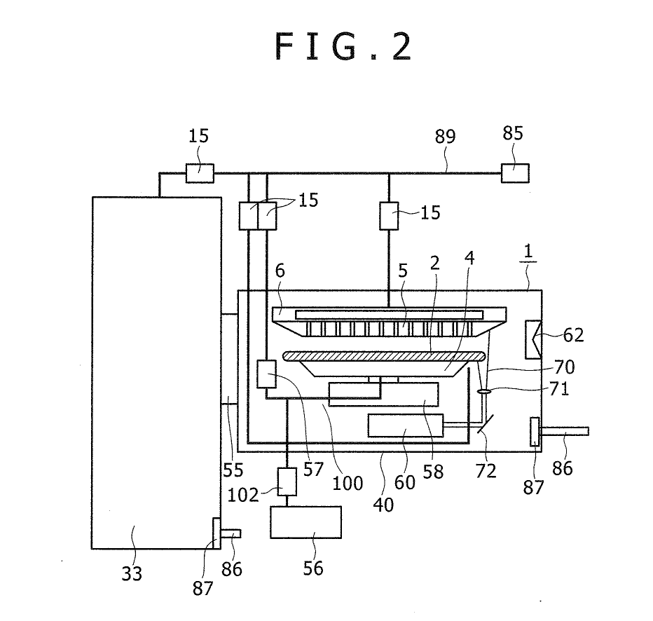

Next, a specific configuration example of the deposit removal unit 1 will be described with reference to FIGS. 2 to 5. First, it is desirable that a deposit can be removed under atmospheric pressure. Accordingly, the invention adopts a method of heating the deposit with a laser beam to a high temperature to evaporate and remove it and does not use reactive gas for removal, so that a processing chamber of the deposit removal unit 1 can be set to an atmospheric environment.

The term “atmospheric environment” is used to distinguish it from a reduced-pressure environment or a vacuum environment in the plasma processing unit, and refers to an environment of atmospheric pressure or substantially atmospheric pressure in the atmosphere-side transfer chamber and the like.

The deposit removal unit 1 includes a processing chamber 40 for performing deposit removal processing; a substantially disc-shaped stage 4, installed substantially in the middle of the processing chamber 40, for mounting the sample 2 thereon; a rotation mechanism 58 for rotating the stage 4 in the circumferential direction; and a laser source 60 for applying a pulsed laser beam to the periphery of the backside of the sample 2 to evaporate and remove the deposit at a high temperature. The processing chamber 40 of the deposit removal unit 1 is connected through a gate valve 55 to the atmosphere-side transfer chamber 33.

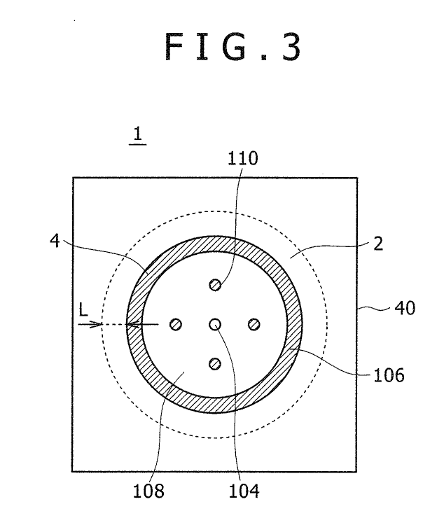

The stage 4 has at the top a sample mounting surface for mounting the sample. As shown in FIG. 3, the sample mounting surface is constructed of an annular contact surface 106 on the outer side, a recessed portion 108 on the inner side, and a plurality of contact surfaces 110 which are provided in the recessed portion 108 and have the same height as that of the annular projection. The outer radius of the sample mounting surface of the stage 4 is smaller than the outer radius of the sample 2 by length L.

Vacuum chuck is used to hold the sample 2 in place on the stage 4 during the rotation of the sample. In order to achieve the function of the vacuum chuck, an exhaust flow passage 104 is opened in the recessed portion 108 of the sample mounting surface of the stage 4. As shown in FIG. 2, the exhaust flow passage 104 is connected through a passage 100 and a valve 102 to a dry pump 56. The exhaust flow passage 104 is also connected through a switching valve 57, a pressure control valve 15, and a passage 89 to a dry air source 85 for supplying dry air for transporting the removed deposit and the like to the outside.

In the stage 4, there are also provided a lift pin for moving the sample up and down to transfer the sample between the sample mounting surface and the atmosphere-side transfer robot 34, a hole for the lift pin, and a lift pin drive mechanism (not shown).

In the case of fixing the sample 2 on the stage 4, with the sample 2 mounted on the sample mounting surface, a space formed between the backside of the sample 2 and the recessed portion 108 is depressurized by the dry pump 56 to function as the vacuum chuck. On the other hand, when the atmosphere-side transfer robot 34 transfers the sample 2 from the sample mounting surface, the switching valve 57 is switched so that the dry air source 85 supplies dry air to return the negative pressure in the recessed portion 108 to atmospheric pressure without delay.

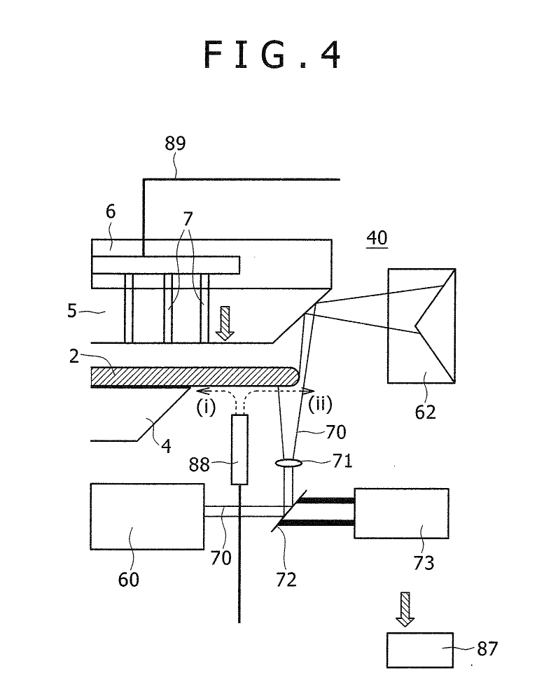

As means for adjusting the irradiation angle of a laser beam applied to the sample 2 mounted on the stage 4, a lens 71 for adjusting a beam irradiation diameter and a mirror 72 are installed in the path of a laser beam 70. As shown in FIG. 4, a mirror controller 73 controls the position of the mirror (arm position), the angle of the mirror, and the position and angle of the lens 71, thus controlling the irradiation angle and position of the laser beam. A beam damper 62 prevents laser light that has not impinged on the periphery of the backside of the sample from being reflected toward the front side of the sample.

Over the stage 4, substantially disc-shaped shower plate 5 and dispersion plate 6 for supplying dry air to the sample 2 are installed. Multiple gas holes 7 are provided in the shower plate 5. The dispersion plate 6 is connected through a pressure control valve 15 and the passage 89 to the dry air source 85. The dry air source 85 is also connected through the passage 89 and pressure control valves 15 to the atmosphere-side transfer chamber 33 and an introduction nozzle 88 (shown in FIG. 4) under the periphery of the stage 4. The atmosphere-side transfer chamber 33 and the deposit removal processing chamber 40 each have an exhaust fan 87 connected to an exhaust duct 86. The operating points of the pressure control valves 15 are set such that the pressure of dry air supplied to the atmosphere-side transfer chamber 33 is higher than the pressure of dry air supplied to the deposit removal processing chamber 40.

The dry air source 85 for supplying dry air to the stage 4 to perform deposit removal processing is also connected to the plasma processing unit 10. As described above, the dry air is supplied to the stage 4 at the time of unloading the sample 2 from the stage 4. In the invention, the dry air refers to low dew point air having a dew point temperature of 0° C. or less.

Air supplied from the shower plate 5 and air supplied to the periphery of the backside of the sample 2 transport the deposit evaporated by laser irradiation to the outside, and shall not be another foreign substance or contamination source for the sample 2. However, any gas other than air can be used as long as it meets this purpose. For example, oxygen, nitrogen, a CF-based gas, or the like may be used. In the invention, such “gases for transporting the deposit removed by evaporation to the outside of the processing chamber 40” are collectively defined as “transporting gas.” The transporting gas may have the function of transporting not only deposits but also minute foreign substances such as reaction products and dust in the atmosphere-side transfer chamber, as in this embodiment. Alternatively, the transporting gas may transport only minute foreign substances in the processing chamber 40.

The diameter of the stage 4 for mounting the sample is smaller than the diameter of the sample, and the periphery of the sample extends off the stage by length L. The deposit is removed by applying the pulsed laser beam 70 to the periphery of the backside of the sample while rotating the sample in the circumferential direction. The laser beam 70 is emitted from the laser source 60 and reflected by the mirror 72. The laser beam reflected by the mirror is adjusted by the lens 71 to a predetermined beam diameter and applied to the extending area of length L on the periphery of the backside of the sample.

In the invention, the deposit is removed by heating the deposit to a high temperature to evaporate it without using chemical reaction with reactive gas. It is necessary to heat the deposit to a high temperature, e.g., about 1000° C. to evaporate it. Accordingly, the laser beam is directly applied to the periphery of the backside of the sample in the atmospheric environment, thus removing the deposit.

When the sample is irradiated with the laser beam, the temperature of the sample rises, and a fine pattern on the front side of the sample becomes damaged if the temperature becomes excessively high. Therefore, it is desirable that the amount of heating of the sample be small. From this point of view, it is desirable to use a pulse oscillation type laser source as the laser source 60. It is desirable that the laser oscillation frequency of the pulse oscillation type fall within the range of 100 Hz to 100 kHz. That is, the pulse oscillation type can apply high energy momentarily when evaporating the deposit by thermal energy, and therefore can control the temperature rise of the whole sample compared to a continuous wave oscillation (CW) type. For example, in the case where the required output of the CW laser is 1000 W, that of the pulsed laser is as small as about 10 W.

Thus, according to the invention, reactive gas is not used, but the pulsed laser beam of high energy is applied to the deposit momentarily and locally, thus evaporating only the irradiated deposit. Due to the momentary and local irradiation, the amount of heating supplied is limited, so that energy is not transferred to the front side of the sample. Therefore, it is desirable that the pulse interval of the laser beam be long, that is, duty ratio: (pulse ON time)/(ON+OFF)=0.01 or less. For example, in the case where the pulse interval is 1 ms and the pulse width is 30 ns, the duty ratio is 0.00003. Although the desirable range of duty ratios depends on the laser oscillation frequency of the pulse oscillation type and other conditions, the duty ratio is preferably within the range of 10⁻⁸ to 10⁻².

Since all deposits in the extending area of length L on the periphery of the backside of the sample need to be irradiated uniformly in a spot shape with the laser beam, the stage 4 is rotated while the laser beam is applied. It is desirable that the rotation speed of the stage 4 be 1 to 20 rpm. In order that the laser beam is applied several times over the entire periphery of the backside of the sample and the laser irradiation does not cause a substantial temperature rise on the front side of the sample, it is desirable that the irradiation time of the laser beam be about 20 seconds for example.

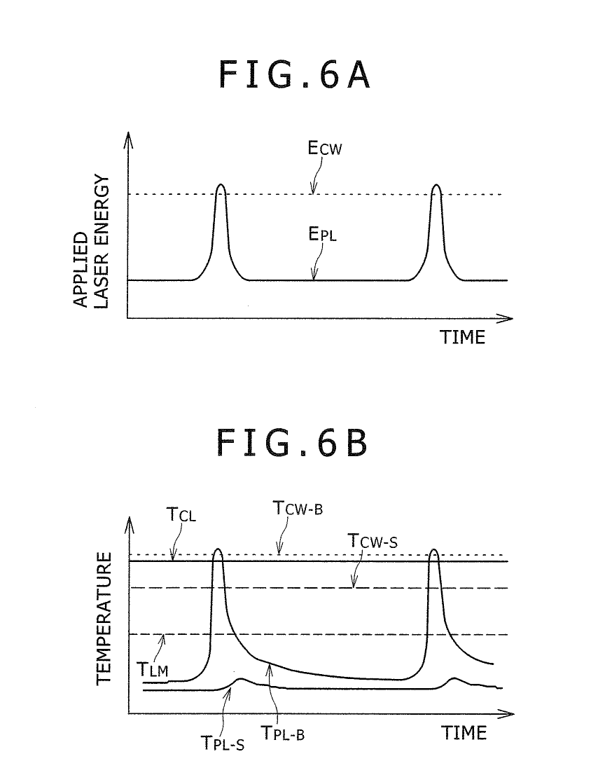

Referring now to FIGS. 6A and 6B, description will be made on an advantage of the invention, that is, the necessity of using the pulsed laser of a high peak power density due to the difficulty of removing the deposit with the CW laser.

FIG. 6A shows temporal changes in energies (ECW: CW laser, EPL: pulsed laser) supplied to the periphery of the backside of the sample. FIG. 6B shows temporal temperature changes (of the pulsed laser and the CW laser) on the front side and backside of the sample when the laser beam is applied with the timing shown in FIG. 6A.

As shown in FIG. 6B, in the case of the pulse oscillation type laser, the irradiation time of one laser pulse is as short as 30 ns for example, and laser pulses are applied at intervals of e.g. 1 ms, that is, 1000000 ns. Consequently, when the periphery of the backside of the sample is heated momentarily so that temperature TPL-B of the periphery of the backside of the sample reaches temperature TCL (e.g., 1000° C.) necessary for deposit removal; due to a thermal-diffusion time much longer than the irradiation time of one laser pulse, temperature TPL-S of the front side of the sample rises little and is maintained at e.g. 200° C. or less. On the other hand, in the case of the CW laser, the periphery of the backside of the sample is always heated. Consequently, when the periphery of the backside of the sample is heated so that temperature TCW-B of the periphery of the backside of the sample reaches temperature TCL (e.g., about 1000° C.) necessary for deposit evaporation, temperature TCW-S of the front side of the sample readily exceeds temperature TLM (e.g., 400° C.) which damages a fine pattern.

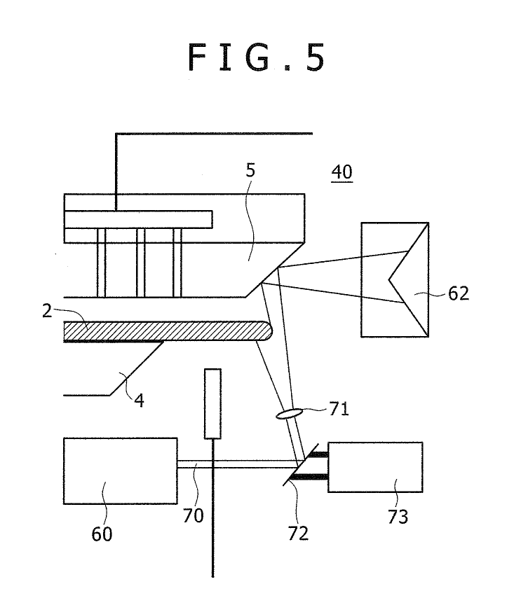

The irradiation position on the sample is adjusted by the angle and radial position of the mirror 72 with respect to the sample. The angle and position of the mirror is controlled by the mirror controller 73 installed beside the optical path of the laser beam. In the example of FIG. 4, the arm of the mirror controller 73 is in an extending state, and the laser beam is applied from substantially directly below the sample. In the example of FIG. 5, the arm of the mirror controller 73 is in a contracting state, and the laser beam is applied from diagonally below the sample. With the structure in which the angle and position of the mirror is thus controlled, the deposit formed from the backside to the front side of the periphery of the sample can be removed with efficiency.

In order to prevent the deposit evaporated by laser irradiation from adhering to the sample again, the shower plate 5 installed opposite to the stage 4 supplies dry air toward the sample. The flow of the air can prevent the deposit evaporated by laser irradiation from flying to the sample.

As shown in FIG. 4, the gas introduction nozzle 88 for supplying dry air is installed between the laser irradiation position of the sample and the stage. That is, there is a risk of taking in air through a slight gap between the stage and the sample when the sample is fixed by vacuum chuck. If air including the evaporated deposit is taken in at the time of the vacuum chuck, the backside of the sample and the stage are contaminated. In order to prevent this, dry air is supplied from the gas introduction nozzle 88 so that only dry air is taken in by the vacuum chuck (gas flow (i) in FIG. 4), and the evaporated deposit is transported in the direction of the periphery of the sample (gas flow (ii) in FIG. 4).

If laser light that has not impinged on the sample bounces in the processing chamber (e.g., bounces off a top plate) and falls on the fine pattern on the front side of the sample, the region is locally heated so that the fine structure may be destroyed. Accordingly, in order for the laser light that has not impinged on the sample to be terminated by the beam damper, the shower plate and the like which are installed above the sample have tapers for reflecting the laser light in predetermined directions. Further, the beam damper 62 is installed to terminate the laser light scattered by these tapers.

It is desirable that the beam through the lens 71 for adjusting the beam irradiation diameter should not be a parallel beam. If the laser beam 70 is a parallel beam, laser power density per unit area of cross section does not decrease with distance. Accordingly, if the parallel laser beam falls on the fine pattern on the front side of the sample, serious damage occurs. In the case where the laser beam 70 is not a parallel beam, even if the beam falls on the fine pattern on the front side of the sample, serious damage does not occur due to decreased laser power density per unit area of cross section.

Since the inner wall of the deposit removal unit becomes contaminated due to re-adhesion of the evaporated deposit, swap parts which are replaceable are preferably used as an inner wall member.

As described, in the deposit removal unit for removing the deposit, the deposit is evaporated by pulsed laser irradiation. If air including the evaporated deposit flows into the atmosphere-side transfer chamber 33, the atmosphere-side transfer chamber becomes contaminated. To prevent this, dry air is supplied to the atmosphere-side transfer chamber and the deposit removal unit, and the pressure in the atmosphere-side transfer chamber 33 is set to be higher than the pressure in the deposit removal unit.

Further, in order that laser scattered light and air including the evaporated deposit do not leak out of the deposit removal unit into a clean room and the like, the atmosphere-side transfer chamber 33 and the deposit removal processing chamber 40 are closed spaces independent of each other, and the gate valve 55 is installed between the deposit removal processing chamber and the atmosphere-side transfer chamber.

Preferably, the dry air (transporting gas) supplied to the atmosphere-side transfer chamber and the deposit removal unit is carried to a purifier through the exhaust fans 87 and the exhaust ducts 86 and returned to the dry air source for circulation.

The system controller 8 according to this embodiment is configured with a program for process execution, a memory, a computer having a database. By way of example, the system controller 8 has an etching control function, a transfer system control function, a deposit removal control function, and an aligner control function. The transfer system control function controls the atmosphere-side transfer chamber 33, the vacuum-side transfer robot 32, the lock chambers 35, and the gate valve to transfer the sample 2 piece by piece among the FOUP 38, the aligner 36, the plasma processing unit 10, and the deposit removal unit 1.

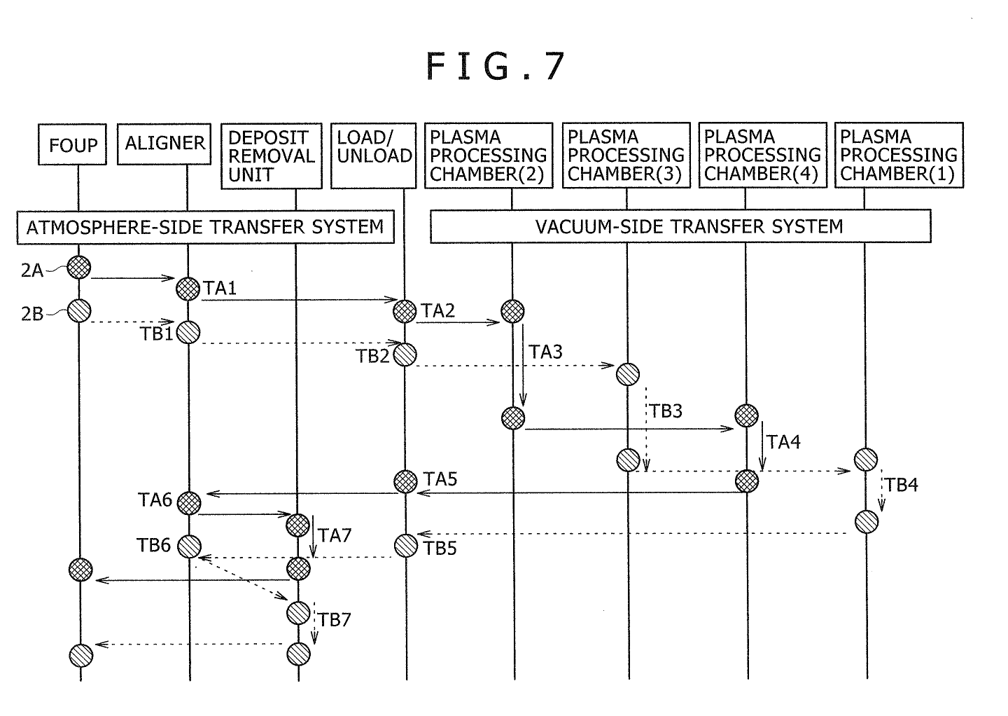

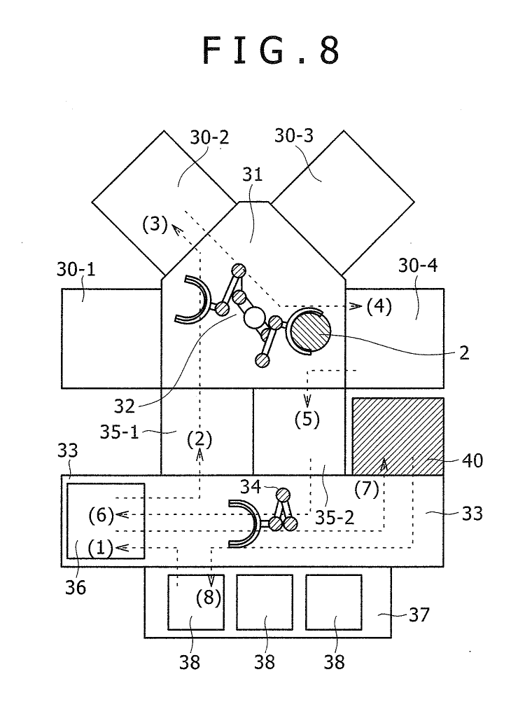

Next, referring to FIGS. 7 to 9B, description will be made on the transfer and processing operations of the sample executed with the functions of the system controller 8 in the plasma processing apparatus according to the invention. FIG. 7 is a time chart showing a processing sequence. FIG. 8 is an illustration showing the flow of transfer of the sample in the plasma processing apparatus.

First, the atmosphere-side transfer robot 34 transfers a sample 2A stored in the FOUP 38 to the aligner 36 from the FOUP 38. The aligner 36 detects the notch position and the center position of the sample. (TA1 in FIG. 7, (1) in FIG. 8)

Next, fine adjustments are made to the position of the arm of the atmosphere-side transfer robot 34 so that the center of the sample is mounted on the predetermined position of the transfer arm, and the sample 2A is transferred from the aligner 36 into the lock chamber (load lock chamber) 35-1. Then, vacuuming is performed in the lock chamber. (TA2 in FIG. 7, (2) in FIG. 8)

Next, the sample 2A is transferred from the lock chamber 35-1 to the vacuum-side transfer chamber 31 and then to the plasma processing chamber 30-2. Then, predetermined etching is performed on the sample. (TA3 in FIG. 7, (3) in FIG. 8)

In the meantime, the atmosphere-side transfer robot 34 transfers another sample 2B stored in the FOUP 38 to the aligner 36 from the FOUP 38. The aligner 36 detects the notch position and the center position of the sample. Further, the atmosphere-side transfer robot 34 transfers the sample 2B from the aligner 36 through the lock chamber (load lock chamber) 35-1 to the plasma processing chamber 30-3. Then, predetermined etching is performed on the sample 2B. (TB1 to TB3 in FIG. 7)

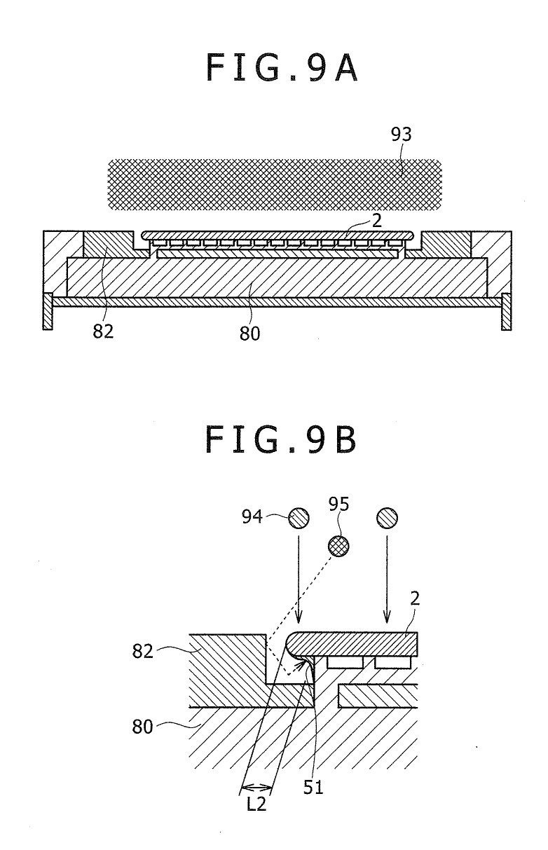

Referring to FIGS. 9A and 9B, description will be made on the cause of the adhesion of the deposit to the periphery of the backside of the sample processed in the plasma processing chamber. FIG. 9A shows the state of plasma processing in the plasma processing chamber. The sample 2 is mounted on the sample mounting surface of a specimen stage 80 installed in the plasma processing chamber and is processed with plasma 93. Reference numeral 82 denotes a focus ring. Generally, in order for the top surface of the specimen stage 80 not to be consumed by plasma incidence, the sample 2 is mounted on the sample mounting surface of the specimen stage 80, extending off the sample mounting surface in the radial direction by about 1 to 2 mm (length L2).

As shown in FIG. 9B, ions 94 generated in the plasma 93 fall perpendicularly on the sample from the plasma. Therefore, few ions fall on the other side the sample, such as the periphery of the backside of the sample extending off the sample mounting surface of the specimen stage 80, whereas neutral particles 95 can fall on the sample and the focus ring 82 at various incident angles and therefore can fall on the other side the sample, bouncing off the sample, an electrode, and the like. Consequently, neutral particles adhere to the periphery (=L2) of the backside of the sample and these are not removed by the impact of ion incidence, thus forming a thick deposit 51.

The sample 2A with the deposit 51 adhering to the periphery of the backside is transferred from the plasma processing chamber 30-2 to the plasma processing chamber 30-4, where ashing (removal processing) is performed on a resist patterned on the front side of the sample 2A. At this time, part of the deposit on the periphery of the backside may be removed. (TA4 in FIG. 7, (4) in FIG. 8)

Further, the ashed sample 2A is transferred from the plasma processing chamber 30-4 to the lock chamber 35-2. Then, the lock chamber is returned from vacuum to atmosphere. (TA5 in FIG. 7, (5) in FIG. 8)

There is a possibility that the sample 2A slips out of place when the lock chamber is returned from the vacuum to the atmosphere. Accordingly, the sample 2A is transferred to the aligner 36, where the sample is held by holding means and the notch position and the center position of the sample 2A are detected. (TA6 in FIG. 7, (6) in FIG. 8)

Next, fine adjustments are made to the position of the arm of the atmosphere-side transfer robot 34 so that the center of the sample 2A is mounted on the predetermined position of the transfer arm, and the sample is transferred from the aligner into the deposit removal unit 1. In the deposit removal unit 1, the pulsed laser is applied to the periphery of the backside of the sample, that is, the whole area of length L2 in the radial direction inwardly from the peripheral end of the sample, thereby evaporating and removing the deposit. (TA7 in FIG. 7, (7) in FIG. 8)

As seen from the description of FIG. 9, it is desirable that the outer diameter of the sample mounting surface in the deposit removal unit 1 be smaller than the outer diameter of the sample mounting surface of the specimen stage 80.

Next, the sample 2A is taken out of the deposit removal unit 1 by the arm of the atmosphere-side transfer robot 34 and returned to the FOUP 38. In this state, the deposit on the periphery of the backside of the sample has been removed; therefore, there is no risk that the carried-in sample contaminates the inside of the FOUP. ((8) in FIG. 8)

The arms of the atmosphere-side transfer robot 34 and the vacuum-side transfer robot 32 and the holding means in the lock chambers 35 and the aligner 36 hold the backside of the sample at a position inside the periphery of the backside of the sample (not less than length L2 inwardly from the peripheral end of the backside of the sample). Therefore, there is no risk that the arms of the vacuum-side transfer robot 32 and the atmosphere-side transfer robot 34 and the holding means of the aligner 36 contaminate the insides of the vacuum-side transfer chamber, the lock chambers, the atmosphere-side transfer chamber, and the FOUP due to the detachment of the deposit.

Meanwhile, in the same way, the sample 2B is transferred from the plasma processing chamber 30-3 and the plasma processing chamber 30-1 after the completion of etching and ashing, through the lock chamber 35-2 to the aligner 36. After the deposit is removed in the deposit removal unit 1, the sample 2B is returned to the FOUP 38.

The following is an example of times required for steps in FIG. 7. Since each of the times required for the sample 2A is approximately equal to that of the sample 2B (e.g., TA1=TB1), the times required for the sample 2B are omitted herein. TA1=TA6=about 10 seconds, TA2=TA5=about 15 to 20 seconds, TA3=about 2 minutes, TA4=about 30 to 60 seconds, and TA7=about 30 seconds.

In this example, since the time required for deposit removal processing in the deposit removal unit 1 is equal to or less than a quarter the time required for etching in the plasma processing chambers 30, a series of steps can be performed successively without reducing the throughput by providing only one deposit removal unit 1 for the four plasma processing chambers.

The example shown in FIGS. 7 and 8 is merely one example of the processing flow. It is needless to say that processing conditions such as transfer routes and the processing contents and times in the plurality of plasma processing chambers can be set arbitrarily in accordance with practical uses.

The processing and transfer operation example of the sample such as a wafer has been described briefly. When the etching apparatus is equipped with the deposit removal unit of the invention, the following advantages can be obtained.

First, in the invention, the deposit is removed by repeating local heating to a high temperature for evaporation without using chemical reaction with reactive gas in the deposit removal processing; therefore, the deposit removal unit can be easily connected to the atmosphere-side transfer chamber of the etching apparatus, so that the entire apparatus configuration can be simplified.

The sample needs to be adjusted to a predetermined position when transferred into the deposit removal unit; therefore, the aligner is needed. If the plasma processing unit and the deposit removal unit are independent of each other, an aligner and an atmosphere-side transfer robot are needed for each unit. In the plasma processing apparatus configured such that the deposit removal unit is connected to the plasma processing unit, the deposit removal unit and the plasma processing unit can share an aligner and a transfer robot; therefore, the cost of the plasma processing apparatus is reduced compared to the case where an aligner and a transfer robot are provided for each unit.

Further, if the plasma processing unit and the deposit removal unit are independent of each other, the sample having the deposit on the periphery of the backside thereof is temporarily stored in the FOUP after the completion of predetermined processing in the plasma processing unit, and then the deposit is transported to the deposit removal unit. In this case, there is a risk that the detachment of the deposit contaminates the insides of the FOUP. Connecting the deposit removal unit to the plasma processing unit can reduce the risk that the detachment of the deposit contaminates the insides of the FOUP.

While the first embodiment has been described above, the deposit removal unit is not limited to the pulsed laser-based system, and may employ any other energy source as long as it is an intermittent energy supply source which functions at substantially atmospheric pressure and can momentarily apply high energy enough to evaporate the deposit by thermal energy to only the backside of the sample.

### Second Embodiment

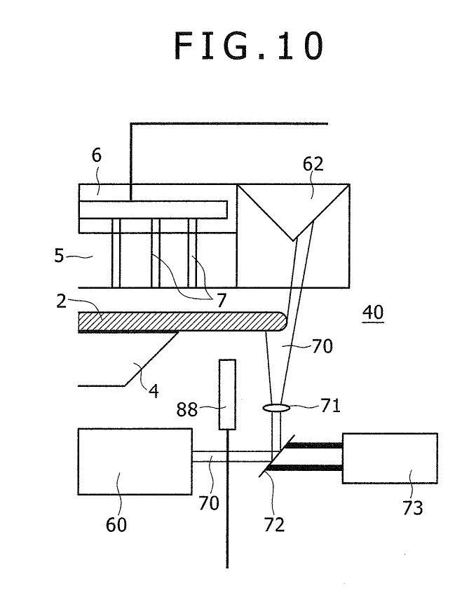

In the first embodiment, the beam damper is installed beside the sample. However, as shown in FIG. 10, the beam damper may be installed above the sample so as to directly terminate laser light that has not impinged on the sample without a mirror or the like reflecting the laser light.

In the example of FIG. 10, the beam damper 62 is integral with the shower plate 5 and the dispersion plate 6 above the periphery of the sample. This embodiment has the same effect as that of the first embodiment.

### Third Embodiment

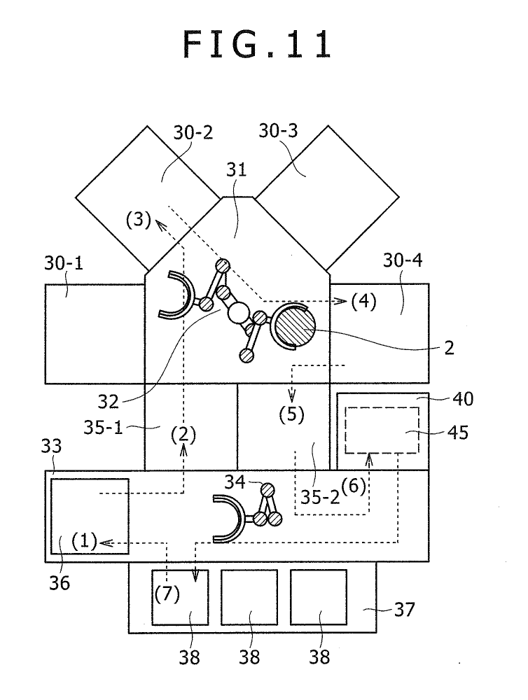

Next, a third embodiment of the invention will be described with reference to FIG. 11. In this embodiment, the aligner is provided in the deposit removal unit 1. FIG. 11 shows an example of the configuration of a plasma processing apparatus according to the third embodiment.

In the deposit removal unit according to this embodiment, in order to implement an aligner function part 45 in the stage in the processing chamber 40, a rotation holding function capable of holding the sample, moving the sample in the radial direction, and rotating the sample subjected to the radial position change is added to the stage, and a position detection sensor and a notch position sensor provided with a light emitting device (installed on a fixed portion below the stage) and a light receiving device (installed on the shower plate) are disposed above and below the periphery of the sample. The aligner function part 45 detects the notch position and the center position of the sample 2 prior to deposit removal processing.

The sample 2 that has undergone plasma processing is transferred out of the lock chamber by the atmosphere-side transfer robot 34. At this time, the relationship between the arm of the transfer robot 34 and the center position of the sample 2 is not accurately controlled. The sample 2 mounted on the arm of the atmosphere-side transfer robot 34 is transferred into the processing chamber 40 of the deposit removal unit 1, where the sample 2 is mounted on the stage 4. Then, the radial position of the sample is adjusted, the stage 4 is rotated with the sample vacuum-chucked to the stage 4, and based on data detected repeatedly by the position detection sensor or the like, the center position and the notch position of the sample 2 are detected by the aligner function part 45. Then, the vacuum chuck is released, and fine adjustments are made to the arm position of the transfer robot 34 so that the center position of the sample coincides with the rotation center of the stage 4 for accurate positioning. Thereafter, the stage 4 is rotated with the sample vacuum-chucked to the stage 4, and the pulsed laser is applied to the periphery of the backside of the sample, thereby evaporating and removing the deposit. Thereafter, the sample is taken out of the deposit removal unit 1 and returned to the FOUP 38 by the atmosphere-side transfer robot 34.

In this embodiment as well, the unit for removing the deposit adhering to the periphery of the backside of the sample is installed in the plasma processing apparatus, thereby advantageously reducing the apparatus cost, enhancing the throughput, and reducing the risk of contaminating the FOUP.

In the foregoing embodiments, the vacuum chuck is used to hold the sample on the stage. However, in place thereof, another holding method such as electrostatic chuck with electrostatic absorption may be employed.

What is claimed is:

1. A plasma processing apparatus comprising a plasma processing chamber for processing a sample in a reduced-pressure environment, the plasma processing apparatus further comprising:
a deposit removal unit for evaporating and removing a deposit adhering to the sample by applying a pulsed laser beam to a periphery of a backside of the sample processed in the plasma processing chamber.

2. The plasma processing apparatus according to claim 1,
wherein the deposit removal unit including:
a processing chamber of an atmospheric environment;
a stage disposed in the processing chamber for mounting the sample thereon;
a rotation mechanism for rotating the stage in a circumferential direction; and
a pulse oscillation type laser for generating a pulsed laser beam which is applied to the sample.

3. The plasma processing apparatus according to claim 2,
wherein a duty ratio of the pulsed laser beam falls within the range of 10⁻⁸ to 10⁻².

4. The plasma processing apparatus according to claim 2,
wherein the deposit removal unit including at least one of irradiation angle adjusting means for adjusting an irradiation angle of a laser beam applied to the sample and irradiation position adjusting means for adjusting an irradiation position of the laser beam.

5. A plasma processing apparatus comprising a plasma processing chamber for processing a sample in a reduced-pressure environment and an atmosphere-side transfer chamber, the plasma processing apparatus further comprising:
a deposit removal unit for evaporating and removing a deposit by applying a pulsed laser beam to a periphery of a backside of the sample held on a stage in a processing chamber connected through a gate valve to the atmosphere-side transfer chamber;
a transporting gas source for supplying transporting gas to both the atmosphere-side transfer chamber and the deposit removal unit; and
an exhaust system from exhausting the transporting gas from the processing chamber and the atmosphere-side transfer chamber, whereby a pressure of the transporting gas in the atmosphere-side transfer chamber is maintained higher than a pressure of the transporting gas in the processing chamber.

6. The plasma processing apparatus according to claim 5,
wherein the transporting gas is dry air.

7. The plasma processing apparatus according to claim 5,
wherein a gas introduction nozzle for supplying the transporting gas is installed between an end of the stage installed in the processing chamber of the deposit removal unit and a laser irradiation position on the periphery of the backside of the sample.

8. The plasma processing apparatus according to claim 5,
wherein there is installed, above a front side of the sample, a beam damper for preventing laser light that has not impinged on the periphery of the backside of the sample from being reflected toward the front side of the sample.

9. A plasma processing apparatus having a plasma processing chamber for processing a sample in a reduced-pressure environment, an atmosphere-side transfer chamber, and an atmosphere-side transfer robot installed in the atmosphere-side transfer chamber, the plasma processing apparatus comprising:
a deposit removal unit for evaporating and removing a deposit formed on the sample by applying a pulsed laser beam to a periphery of a backside of the sample in an atmospheric environment,
wherein the deposit removal unit is configured such that the sample can be transferred by the atmosphere-side transfer robot between the deposit removal unit and the atmosphere-side transfer chamber.

10. The plasma processing apparatus according to claim 9,
wherein the plasma processing chamber includes a specimen stage having a sample mounting surface for holding the sample,
the deposit removal unit includes:
a stage, disposed in the processing chamber, having a sample mounting surface for mounting the sample thereon;
a rotation mechanism for rotating the stage in a circumferential direction; and
a pulsed laser source for applying a pulsed laser beam to the periphery of the backside of the sample extending off the sample mounting surface, and
an outer diameter of the sample mounting surface of the stage is equal to or smaller than an outer diameter of the sample mounting surface of the specimen stage.
